(19) United States
(12) Patent Application Publication
(10) Pub. No.: US 2011/0272737 A1
(43) Pub. Date: Nov. 10, 2011

(54) TRANSISTOR AND TRANSISTOR CONTROL SYSTEM

(75) Inventors: Kenichiro TANAKA, Osaka (JP); Tetsuzo Ueda, Osaka (JP)

(73) Assignee: Panasonic Corporation, Osaka (JP)

(21) Appl. No.: 13/183,830

(22) Filed: Jul. 15, 2011

Related U.S. Application Data
(63) Continuation of application No. PCT/JP2009/005357, filed on Oct. 14, 2009.

(30) Foreign Application Priority Data
Feb. 18, 2009 (JP) 2009-035435

(51) Int. Cl. H01L 29/12

(52) U.S. Cl. 257/183; 257/E29.068

(57) ABSTRACT

A transistor includes a transistor body, and a stress application section applying stress to the transistor body. The transistor body includes a formation substrate, and a first semiconductor layer and a second semiconductor layer which are sequentially stacked on the formation substrate. The second semiconductor layer having a wider bandgap than the first semiconductor layer. The stress application section applies stress to the transistor body so that tensile stress applied to the second semiconductor layer increases in accordance with an increase in a temperature.

### CROSS-REFERENCE TO RELATED APPLICATION

This is a continuation of PCT International Application PCT/JP2009/005357 filed on Oct. 14, 2009, which claims priority to Japanese Patent Application No. 2009-035435 filed on Feb. 18, 2009. The disclosures of these applications including the specifications, the drawings, and the claims are hereby incorporated by reference in their entirety.

### BACKGROUND

The present disclosure relates to transistors and transistor control systems, and more particularly to power transistors made of nitride semiconductor and control systems of the power transistors.

Nitride semiconductor such as gallium nitride (GaN) has a wider bandgap, a larger breakdown field, and higher electron saturated drift velocity than silicon (Si), gallium arsenide (GaAs), etc. In a hetero structure between aluminum gallium nitride (AlGaN) and gallium nitride (GaN), spontaneous polarization and piezoelectric polarization cause a two-dimensional electron gas (2DEG) layer at the hetero interface, and sheet carrier concentration of 1×10¹³ cm⁻² or more is obtained without doping impurities. A high electron mobility transistor (HEMT) can be provided using a highly concentrated 2DEG layer as a carrier. Having the characteristics of low on-resistance and a high breakdown voltage, HEMTs made of nitride semiconductor are expected to exhibit excellent characteristics as power transistors used in power supply circuits etc. (See, for example, S. Arulkumaran, et al., Enhancement Of Breakdown Voltage By AlN Buffer Layer Thickness In AlGaN/GaN High-Electron-Mobility Transistors On 4 In. Diameter Silicon, APPLIED PHYSICS

### SUMMARY

However, a conventional HEMT has the problem that sheet resistance significantly increases in accordance with a rise in a temperature. When a large current flows in a HEMT, the HEMT is heated to increase the temperature. This increases the sheet resistance. When the sheet resistance increases, the HEMT is further heated to further increase the sheet resistance. Therefore, the characteristics that the sheet resistance increases in accordance with a temperature rise are fatal in a power transistor in which a large current flows.

On the other hand, the present inventors found a method of increasing sheet carrier concentration of a HEMT in accordance with an increase in a temperature.

It is an objective of the present disclosure to provide a transistor with a small fluctuation in sheet resistance due to a temperature change using a method of increasing sheet carrier concentration of a HEMT in accordance with an increase in a temperature.

In order to achieve the objective, an example transistor includes a stress application section applying stress corresponding to a temperature to a transistor body.

Specifically, the example transistor includes a transistor body including a formation substrate, and a first semiconductor layer and a second semiconductor layer which are sequentially stacked on the formation substrate, the second semiconductor layer having a wider bandgap than the first semiconductor layer; and a stress application section applying stress to the transistor body so that tensile stress applied to the second semiconductor layer increases in accordance with an increase in a temperature.

The example transistor includes the stress application section applying stress to the transistor body. Thus, the tensile stress applied to the second semiconductor layer increases in accordance with an increase in the temperature. The increase in the tensile stress applied to the second semiconductor layer increases piezoelectric polarization occurring in the second semiconductor layer. This compensates reduction in carrier concentration according to a temperature rise, thereby holding sheet resistance at an almost constant level. As a result, a transistor with a small fluctuation in sheet resistance due to a temperature change can be provided.

In the example transistor, the stress application section may be a holding substrate made of bimetal. The transistor body may be fixed on the holding substrate. In this case, the bimetal may be a combination of copper and aluminum.

The stress application section may include a holding substrate which is a piezoelectric bimorph, and a voltage application circuit applying a voltage to the holding substrate in accordance with a temperature. The transistor body may be fixed on the holding substrate.

In this case, the stress application section may include a temperature detection section detecting a temperature of the transistor body. The voltage application circuit may apply a voltage to the holding substrate in accordance with the temperature detected by the temperature detection section.

In the example transistor, the holding substrate may be warped in a direction in which concentration of carriers generated at an interface between the first semiconductor layer and the second semiconductor layer increases.

In the example transistor, the holding substrate may be warped in a direction in which a change in sheet resistance due to a temperature is compensated.

In the example transistor, the holding substrate may be warped to have a convex upward shape. In this case, the transistor body may be fixed on the holding substrate with the formation substrate facing down.

In the example transistor, the holding substrate may be warped to have a convex downward shape. In this case, the transistor body may include an insulating film formed on the second semiconductor layer, and may be fixed on the holding substrate with the insulating film facing down.

In the example transistor, the stress application section may include a holding substrate on which the transistor body is placed, a stress application substrate fixed on the holding substrate to interpose the transistor body therebetween, and a pressing pillar located between the stress application substrate and the transistor body, and stretching in accordance with the temperature.

In this case, the pressing pillar may be made of a material having a higher coefficient of thermal expansion than the formation substrate. Alternately, the pressing pillar may include a pressing pillar body made of a piezoelectric material, and a voltage application circuit applying a voltage to the pressing pillar in accordance with the temperature.

In the example transistor, the stress application section may be a stress application film formed on the second semiconductor layer, and having a higher coefficient of thermal expansion than the formation substrate.

In the example transistor, the stress application section may be a stress application film formed on a surface of the formation substrate, which is opposite to the first semiconductor layer, and having a lower coefficient of thermal expansion than the formation substrate.

In the example transistor, a maximum value of the stress applied to the transistor body by the stress application section is preferably a value at which a curvature radius of the formation substrate is not less than 250 m.

A transistor control system according to the present disclosure includes a transistor body including a formation substrate, a first semiconductor layer and a second semiconductor layer which are sequentially stacked on the formation substrate, the second semiconductor layer having a wider bandgap than the first semiconductor layer; a temperature detection section detecting a temperature of the transistor body; and a stress application section applying tensile stress at a level corresponding to an output of the temperature detection section to the second semiconductor layer.

According to the transistor and the control system of the transistor of the present disclosure, a transistor with a small fluctuation in sheet resistance due to a temperature change can be provided.

### BRIEF DESCRIPTION OF THE DRAWINGS

FIG. 1 is a graph illustrating temperature dependence of mobility and carrier concentration in a HEMT.

FIG. 2 is a graph illustrating temperature dependence of sheet resistance in a HEMT.

FIG. 3 is a schematic view illustrating generation principles of a two-dimensional electron gas layer in a HEMT.

FIG. 4 is a cross-sectional view illustrating a transistor according an embodiment.

FIG. 5 is a cross-sectional view illustrating a state of the transistor according to the embodiment when a temperature rises.

FIG. 6 is a graph illustrating comparison of temperature dependence of sheet resistance between the transistor according to the embodiment and a conventional transistor.

FIG. 7 is a cross-sectional view of a transistor according to a variation of the embodiment.

FIG. 8 is a cross-sectional view of a transistor according to a variation of the embodiment.

FIG. 9 is a cross-sectional view of a transistor according to a variation of the embodiment.

FIG. 10 is a cross-sectional view of a transistor according to a variation of the embodiment.

FIG. 11 is a cross-sectional view of a transistor according to a variation of the embodiment.

FIG. 12 is a cross-sectional view of a transistor according to a variation of the embodiment.

FIG. 13 is a cross-sectional view of a transistor according to a variation of the embodiment.

### DETAILED DESCRIPTION

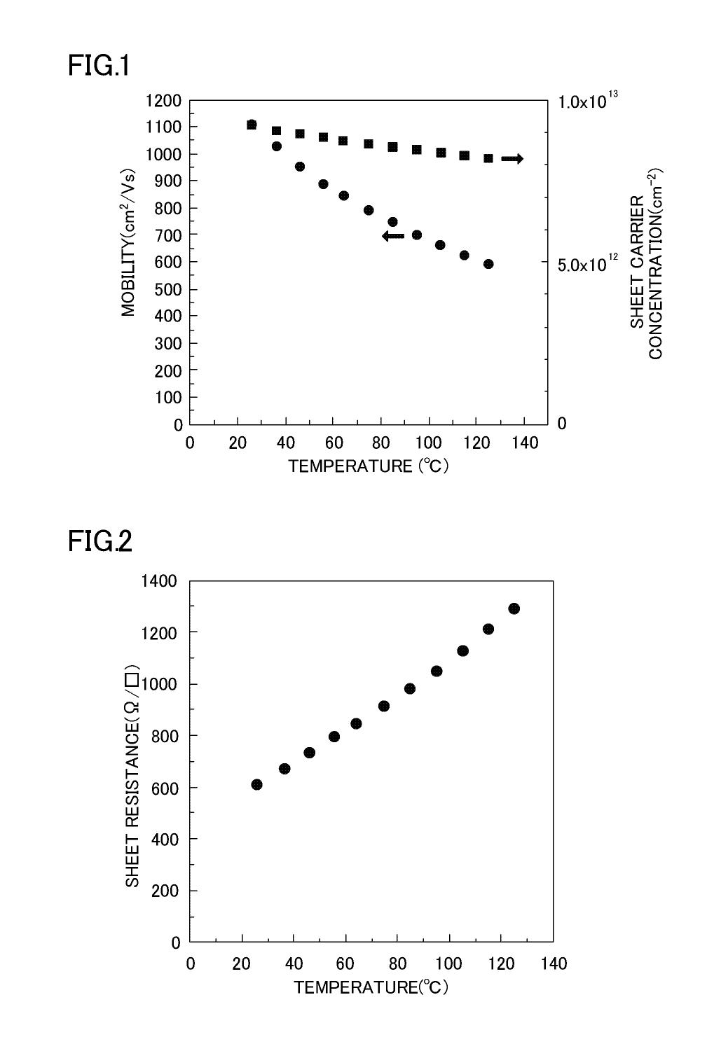

First, basic principles will be described. FIG. 1 illustrates a result of measuring relation between mobility μ and sheet carrier concentration Nₛ, and a temperature in a HEMT formed by stacking a GaN layer and an AlGaN layer. As shown in FIG. 1, both the mobility μ and the sheet carrier concentration Nₛ decrease in accordance with a rise in the temperature. FIG. 2 illustrates relation between the sheet resistance Rₛₕ of the channel and the temperature. As shown in FIG. 2, the sheet resistance Rₛₕ increases with an increase in the temperature. For example, when the temperature is 125° C., the sheet resistance Rₛₕ is twice or more as great as that at a room temperature.

The sheet resistance Rₛₕ of the channel is inversely proportional to the reciprocals of the mobility μ and the sheet carrier concentration Nₛ. The relation between the sheet resistance Rₛₕ, and the mobility μ and the sheet carrier concentration Nₛ is represented by Rₛₕ^{∝}1/(Nₛμ). Therefore, in order to mitigate an increase in the sheet resistance due to a temperature rise, reduction in the mobility μ and the sheet carrier concentration Nₛ caused by the temperature rise may be compensated.

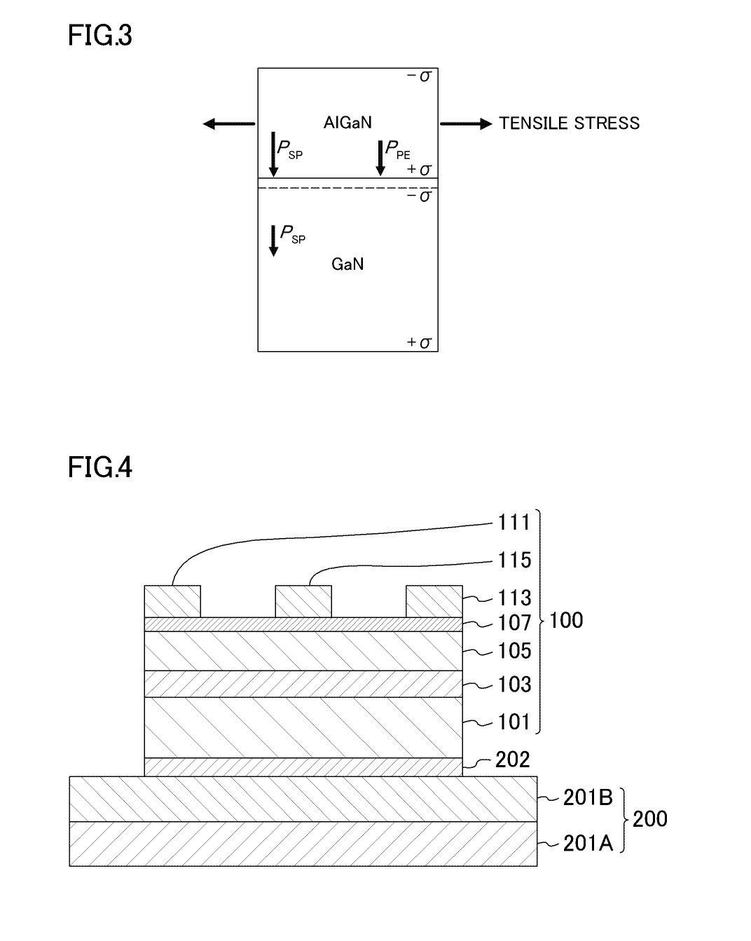

The sheet carrier concentration Nₛ of a HEMT is a sum of a component generated by spontaneous polarization and a component generated by piezoelectric polarization. As shown in FIG. 3, when the AlGaN layer is stacked on the GaN layer, tensile stress caused by a difference in a lattice constant between the AlGaN layer and the GaN layer is applied to the AlGaN layer. The tensile stress causes piezoelectric polarization P_{PE} in the AlGaN layer. Polarization, which is a sum of its spontaneous polarization P_{SP} and the piezoelectric polarization P_{PE}, occurs in the AlGaN layer. This generates positive polarization charge +σ at the AlGaN layer side of the interface between the AlGaN layer and the GaN layer. On the other hand, electrons −σ for neutralizing positive polarization charge +σ are drawn to the GaN layer side of the interface between the AlGaN layer and the GaN layer to generate two-dimensional electron gas. Thus, if the tensile stress applied to the AlGaN layer can be increased, the piezoelectric polarization P_{PE} occurring in the AlGaN layer can be increased. By increasing the piezoelectric polarization P_{PE}, the sheet carrier concentration Nₛ increases.

As described above, when the tensile stress applied to the AlGaN layer is gradually increased with an increase in the temperature, reduction in the sheet carrier concentration N, with the increase in the temperature is considered to be compensated to mitigate an increase in the sheet resistance Rₛₕ of the 2DEG layer. Then, the present inventors realized a transistor with a mitigated increase in channel resistance due to a temperature change by providing a stress application section applying stress to a transistor body in accordance with an increase in a temperature. The transistor will be described in detail using an embodiment.

### Embodiment

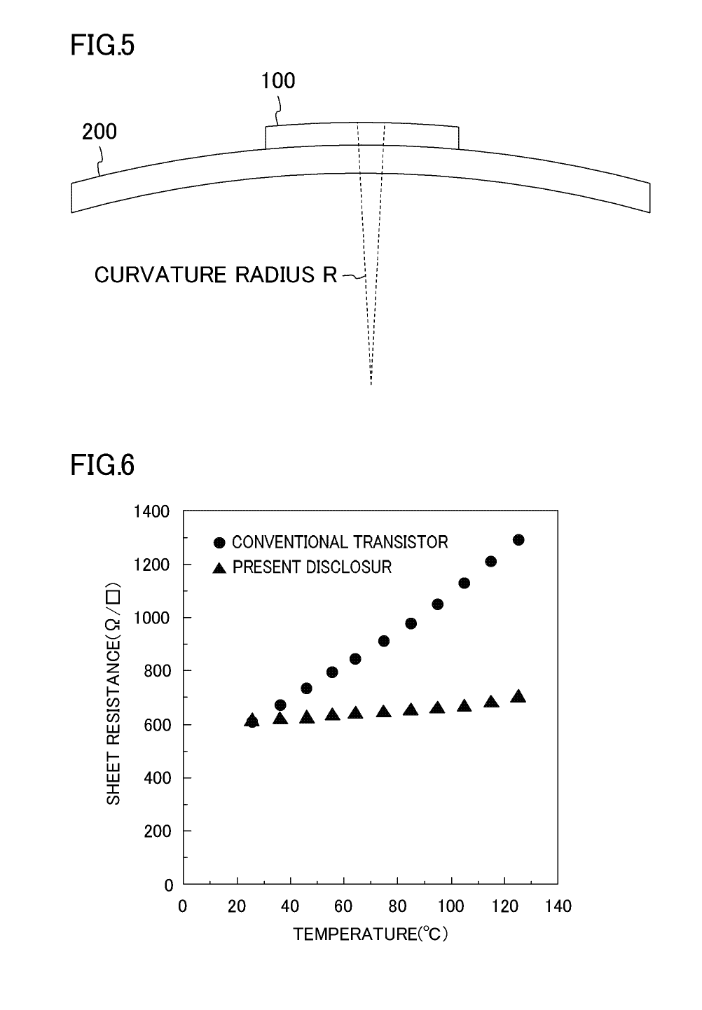

FIG. 4 illustrates a cross-sectional structure of an example transistor. As shown in FIG. 4, a transistor body 100 which is a HEMT made of nitride semiconductor is fixed on a holding substrate 200 which is a stress application section by solder 202.

The transistor body 100 is formed on a formation substrate 101. The formation substrate 101 may be a Si substrate, a SiC substrate, a sapphire substrate or a GaN substrate, etc. A low-buffer layer 103 made of aluminum nitride (AlN) is formed on the formation substrate 101. A semiconductor layer is formed on the low-buffer layer 103. The semiconductor layer includes a first semiconductor layer 105 made of undoped GaN and a second semiconductor layer 107 formed on the first semiconductor layer 105 and made of undoped AlGaN. A source electrode 111, a gate electrode 115, and a drain electrode 113 are formed on the second semiconductor layer 107. Each of the source electrode 111 and the drain electrode 113 may be an ohmic electrode formed by stacking e.g., titanium (Ti) and aluminum (Al). The gate electrode 115 is, for example, a Schottky electrode formed by stacking platinum (Pt) and gold (Au).

The holding substrate 200 is made of bimetal formed by stacking a low-expansion layer 201A made of copper and having a thickness of 1200 μm, and a high-expansion layer 201B made of Al and having a thickness of 1000 μm. The low-expansion layer 201A of copper has a coefficient of thermal expansion of 17.0×10⁻⁶/° C., while the high-expansion layer 201B of Al has a coefficient of thermal expansion of 23.5×10⁻⁶/° C. The holding substrate 200 is warped by the difference in the coefficient of thermal expansion between the low-expansion layer 201A and the high-expansion layer 201B, when a temperature rises as shown in FIG. 5. A curvature radius R indicating the degree of the warpage gradually decreases with the increase in the temperature. When the curvature radius R of the holding substrate 200 decreases with an increase in the temperature, the curvature radius R of the transistor body 100, which is fixed to the holding substrate 200, also decreases. The holding substrate 200 warps so that a top surface which is the high-expansion layer 201B has a convex upward shape. When the transistor body 100 is fixed on the holding substrate 200 with the semiconductor layer facing up, the holding substrate 200 warps so that the top surface of the semiconductor layer has a convex upward shape. This gradually raises the level of tensile stress applied to the second semiconductor layer 107 of AlGaN with an increase in the temperature. As a result, the sheet carrier concentration N, of the 2DEG layer at the interface between the first semiconductor layer 105 and the second semiconductor layer 107 can be increased with an increase in the temperature, thereby mitigating an increase in the sheet resistance Rₛₕ with a temperature change.

FIG. 6 illustrates temperature dependence of sheet resistance in the transistor of this embodiment including the transistor body 100 fixed on the holding substrate 200 of bimetal, and a conventional transistor including a transistor body fixed on a holding substrate of copper. As shown in FIG. 6, in the conventional transistor, sheet resistance rapidly increases with an increase in the temperature. By contrast, in the transistor of this embodiment, sheet resistance hardly increases with an increase in the temperature. This result shows that reduction in the sheet carrier concentration with the increase in the temperature is compensated by increasing tensile stress applied to the second semiconductor layer 107 with the increase in the temperature. As such, by fixing the transistor body 100 on the holding substrate 200 of bimetal which is the stress application section, a transistor with a small fluctuation in sheet resistance due to a temperature change is provided.

A change amount of the curvature radius of the holding substrate 200 may be determined based on characteristics of needed transistors. Note that, when the curvature radius of the holding substrate 200 excessively decreases, the stress applied to the transistor body 100 exceeds a predetermined value, and the transistor body 100 may be damaged. In the transistor body 100 of this embodiment, when the curvature radius of the formation substrate 101 is less than 250 m, the transistor body 100 is damaged. Therefore, the curvature radius of the holding substrate 200 is preferably 250 m or more.

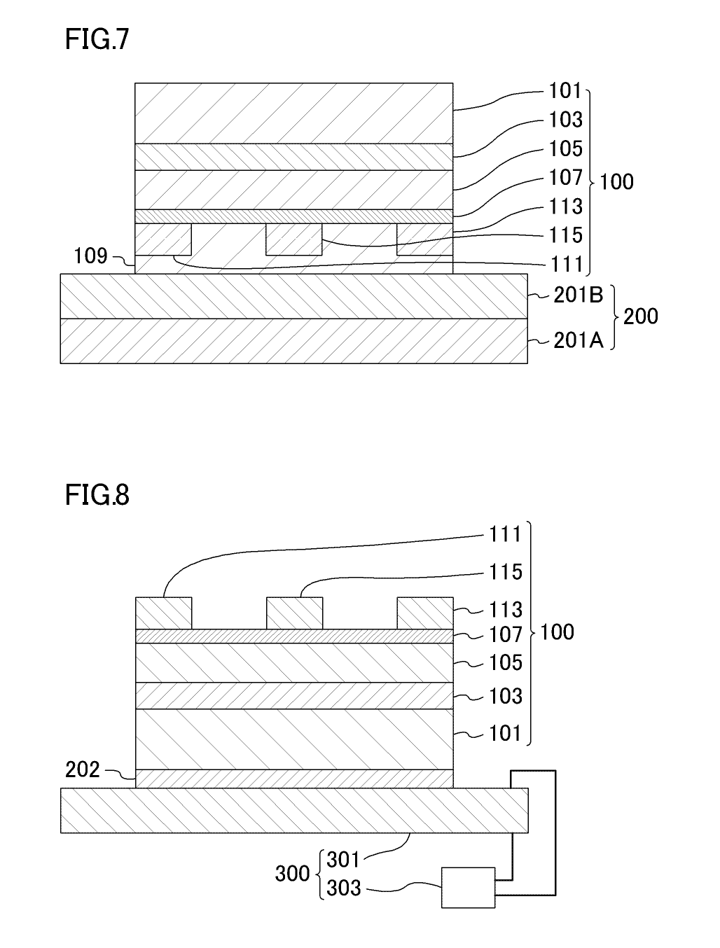

In this embodiment, the holding substrate 200 includes the high-expansion layer 201B on the upper side. Thus, the transistor body 100 is fixed on the holding substrate 200 with the formation substrate 101 located on the lower side. However, as shown in FIG. 7, it may be fixed with the formation substrate 101 located on the upper side. In this case, an insulating film 109 is formed on the second semiconductor layer 107, and the transistor body 100 may be fixed with the insulating film 109 located on the lower side. The holding substrate 200 may be formed with the low-expansion layer 201A located on the upper side, and may be warped by an increase in the temperature so that the top surface has a convex downward shape.

An example has been described where the low-expansion layer 201A is made of copper, and the high-expansion layer 201B is made of Al, the materials are not limited thereto and may be a combination of two types of materials having different coefficients of thermal expansion. By selection of the material, the minimum curvature radius and the change rate of the curvature radius due to the temperature can be adjusted. With this feature, a most suitable holding substrate 200 can be provided in accordance with characteristics of the transistor body 100. Two materials are not necessarily bonded, three or more types of materials may be bonded to form the holding substrate 200.

A material containing Al dispersed in SiC may be used, and two plates with different Al concentration are bonded to compensate a temperature change caused by sheet resistance.

In this embodiment, the holding substrate 200 made of bimetal with a curvature radius changing in accordance with the temperature is used as the stress application section. However, the stress application section may be made of other materials, as long as it can apply tensile stress to the second semiconductor layer 107 in accordance with the temperature. For example, as shown in FIG. 8, the stress application section may be a holding substrate set 300 including a holding substrate body 301 which is a piezoelectric bimorph with a curvature radius changing in accordance with an applied voltage, and a voltage application circuit 303 applying a voltage corresponding to the temperature to the holding substrate body 301. In this case, as well, the advantage similar to that in the case where the stress application section is the holding substrate 200 of bimetal.

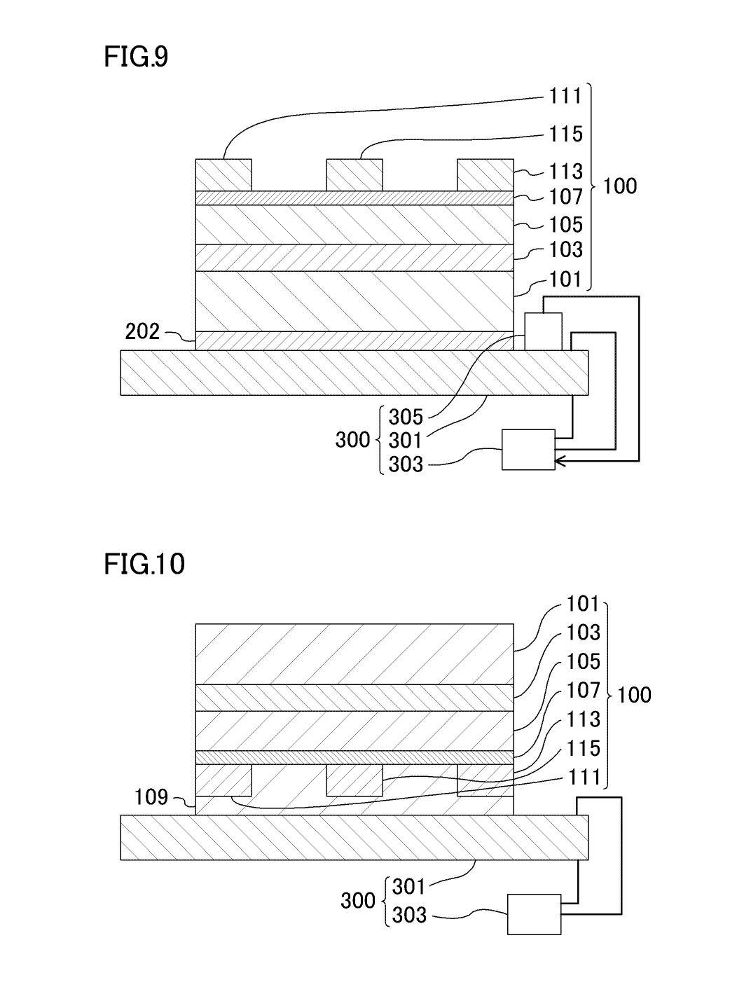

The voltage application circuit 303 may apply a voltage to the holding substrate body 301 in accordance with, for example, a pattern set in advance. Furthermore, as shown in FIG. 9, a temperature detection section 305 detecting the temperature of the transistor body 100 may be provided so that an output of the temperature detection section 305 controls the voltage application circuit 303. In this case, the temperature detection section 305 may not necessarily actually measure the temperature of the transistor body 100, and may measure the temperature of surroundings to estimate the temperature of the transistor body 100. Furthermore, as shown in FIG. 10, the transistor body 100 may be fixed with the formation substrate 101 located on the upper side. The piezoelectric bimorph may be formed by depositing lead zirconate titanate (PZT) on metal such as Al by sputtering etc.

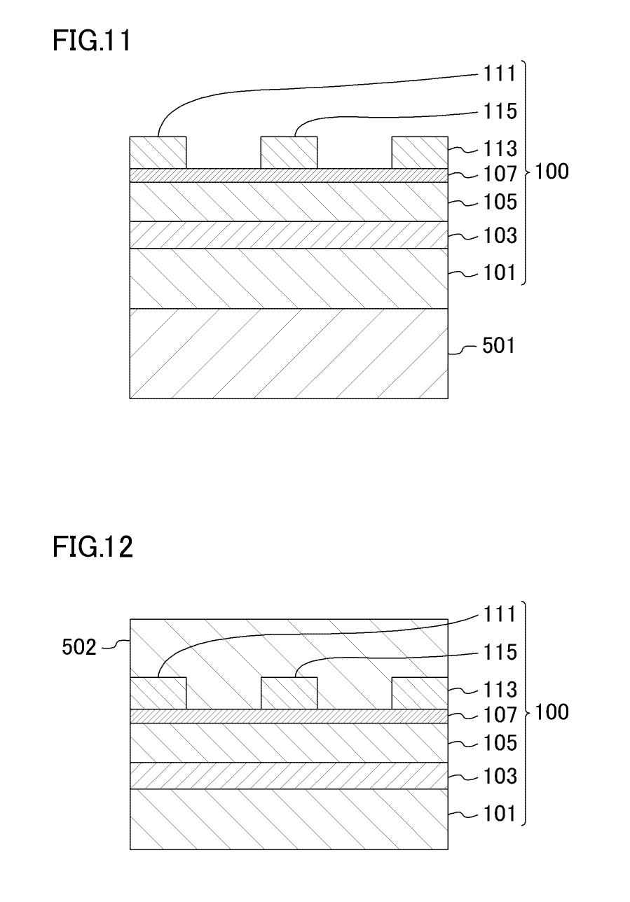

As shown in FIG. 11, the stress application section may be a stress application film 501 formed on a surface (back surface) of the formation substrate 101 which is opposite to the surface provided with the semiconductor layer. In this case, a film having a lower coefficient of thermal expansion than the formation substrate 101 may be used as the stress application film 501. For example, when the formation substrate 101 is a Si substrate, the stress application film 501 may be made of SiO₂, a nickel-iron alloy with reduced temperature dependence, etc.

In the structure of this embodiment, the stress application film 501 is formed on the back surface of the formation substrate 101, and thus, there is no problem even when the stress application film 501 is conductive. In the structure shown in FIG. 11, the tensile stress applied to the second semiconductor layer 107 increases in accordance with a temperature rise, and thus, the carrier concentration of the 2DEG layer increases. This results in reduction in temperature dependence of the channel resistance in the transistor.

The stress may be applied not from the formation substrate 101, but from the semiconductor layer. In this case, as shown in FIG. 12, a stress application film 502 may be formed on the second semiconductor layer 107. In this case, a film having a higher coefficient of thermal expansion than the formation substrate 101 may be used as the stress application film 502. For example, when the formation substrate 101 is a Si substrate, the stress application film 502 may be made of LiNbO₃, LiTaO₃, BaTiO₃, etc. When the stress application film 502 is formed on the second semiconductor layer 107, an insulating film is preferably used no to influence the transistor body 100 at the time of applying a current.

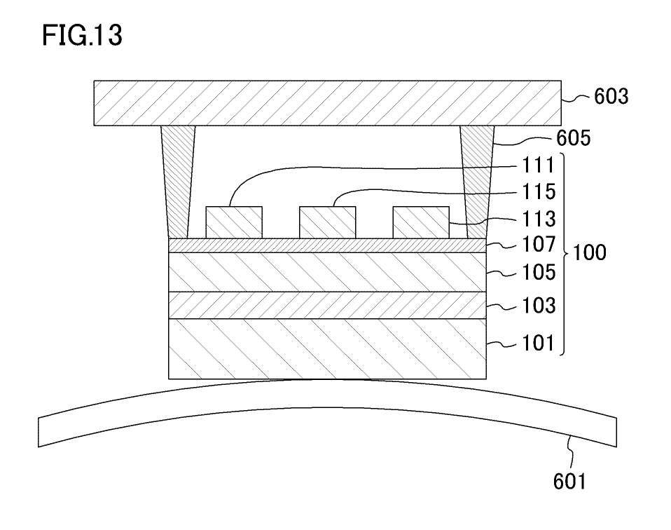

The stress application section may have the structure shown in FIG. 13. As shown in FIG. 13, the stress application section includes a holding substrate 601 with a warped main surface, a stress application substrate 603, and a pressing pillar 605 stretched by heat. The stress application substrate 603 is fixed on the holding substrate 601 to interpose the transistor body 100 therebetween. The stress application substrate 603 may be fixed by any method as long as it can be fixed on the holding substrate 601 at a distance. For example, a pillar may be provided between the holding substrate 601 and the stress application substrate 603 and may be fixed. The transistor body 100 is placed between the holding substrate 601 and the stress application substrate 603. The transistor body 100 is pressed onto the holding substrate 601 by the pressing pillar 605 located between the stress application substrate 603 and the transistor body 100. The pressing pillar 605 is made of a material with a high coefficient of thermal expansion. In accordance with an increase in the temperature, force of pressing the transistor body 100 onto the holding substrate 601 gradually increases. This warps the transistor body 100, and the curvature radius decreases in accordance with an increase in the temperature. Thus, since the tensile stress applied to the second semiconductor layer 107 increases with a temperature rise, the carrier concentration of the 2DEG layer increases, resulting in reduction in the temperature dependence of the channel resistance in the transistor.

The coefficient of thermal expansion of the material used for the pressing pillar 605 may be determined as appropriate in accordance with the stress applied to the transistor body. Note that, in order to efficiently apply stress, the pressing pillar 605 may be made of a material having a higher coefficient of thermal expansion than the holding substrate 601, the stress application substrate 603, and the formation substrate 101.

The pressing pillar 605 may be a combination of a pressing pillar body made of a material having a piezoelectric effect, and a voltage application circuit applying a voltage to the pressing pillar body in accordance with the temperature. Furthermore, a temperature detection section detecting the temperature of the transistor body 100 may be provided to control the voltage application circuit based on the detected result.

In FIG. 13, the holding substrate 601 has the shape that the top surface is warped to have a convex upward shape. With this configuration, tensile stress can be efficiently applied to the second semiconductor layer 107. However, the holding substrate 601 is not necessarily warped. While an example has been described where the transistor body 100 is placed on the holding substrate 601 with the formation substrate 101 located at the lower side, the transistor body 100 may be placed with the formation substrate 101 located on the upper side. In this case, the center of the transistor body 100 may be pressed by the pressing pillar 605. The transistor body 100 may be warped by pressing, and may be fixed on the holding substrate 601 by adhesive such as solder.

Note that, while in this embodiment, solder has been provided as an example method of bonding the HEMT and the holding substrate, the method is not limited thereto. For example, when a HEMT is formed on a Si substrate, the side of the Si substrate is placed on the holding substrate shown in this embodiment, and then annealing is performed in a hydrogen atmosphere while applying pressure, thereby bonding the HEMT to the holding substrate.

While in this embodiment, the first semiconductor layer 105 is made of GaN and the second semiconductor layer 107 is made of AlGaN, semiconductor layers with other compositions may be used as long as the second semiconductor layer 107 has a wider bandgap than the first semiconductor layer 105. For example, a nitride semiconductor layer with a given composition containing N and at least one of In, Ga, or Al as constituent elements. Furthermore, the semiconductor is not limited to two-dimensional or three-dimensional compound semiconductor, and may be four- or more-dimensional compound semiconductor. The structures of the electrodes, etc. may be changed as appropriate as long as the HEMT includes a semiconductor layer having a hetero junction interface.

While in this embodiment, an example has been described where the nitride semiconductor is used in the HEMT, the present disclosure is clearly effective as long as the piezoelectric effect generates the 2DEG layer. Therefore, the structure shown in this embodiment is applicable to the case where a material other than nitride semiconductor is used. For example, it is applicable to a semiconductor device including the first semiconductor layer 105 made of ZnO, and the second semiconductor layer 107 made of ZnMgO, and a 2DEG layer generated at the interface between ZnO and ZnMgO.

According to the transistor and the control system of the transistor of the present disclosure, a transistor with a small change in channel resistance with a temperature change can be provided. In particular, the transistor and the control system of the transistor of the present disclosure are useful as a power transistor and the control system of the power transistor made of nitride semiconductor.

What is claimed is:

1. A transistor comprising:
a transistor body including a formation substrate, and a first semiconductor layer and a second semiconductor layer which are sequentially stacked on the formation substrate, the second semiconductor layer having a wider bandgap than the first semiconductor layer; and
a stress application section applying stress to the transistor body so that tensile stress applied to the second semiconductor layer increases in accordance with an increase in a temperature.

2. The transistor of claim 1, wherein
the stress application section is a holding substrate made of bimetal, and
the transistor body is fixed on the holding substrate.

3. The transistor of claim 2, wherein
the bimetal is a combination of copper and aluminum.

4. The transistor of claim 1, wherein
the stress application section includes
a holding substrate which is a piezoelectric bimorph, and
a voltage application circuit applying a voltage to the holding substrate in accordance with a temperature, and
the transistor body is fixed on the holding substrate.

5. The transistor of claim 4, wherein
the stress application section includes a temperature detection section detecting a temperature of the transistor body, and
the voltage application circuit applies a voltage to the holding substrate in accordance with the temperature detected by the temperature detection section.

6. The transistor of claim 2, wherein
the holding substrate is warped in a direction in which concentration of carriers generated at an interface between the first semiconductor layer and the second semiconductor layer increases.

7. The transistor of claim 2, wherein
the holding substrate is warped in a direction in which a change in sheet resistance due to a temperature is compensated.

8. The transistor of claim 2, wherein
the holding substrate is warped to have a convex upward shape.

9. The transistor of claim 8, wherein
the transistor body is fixed on the holding substrate with the formation substrate facing down.

10. The transistor of claim 2, wherein
the holding substrate is warped to have a convex downward shape.

11. The transistor of claim 10, wherein
the transistor body includes an insulating film formed on the second semiconductor layer, and is fixed on the holding substrate with the insulating film facing down.

12. The transistor of claim 1, wherein
the stress application section includes
a holding substrate on which the transistor body is placed,
a stress application substrate fixed on the holding substrate to interpose the transistor body therebetween, and
a pressing pillar located between the stress application substrate and the transistor body, and stretching in accordance with the temperature.

13. The transistor of claim 12, wherein
the pressing pillar is made of a material having a higher coefficient of thermal expansion than the formation substrate.

14. The transistor of claim 12, wherein
the pressing pillar includes
a pressing pillar body made of a piezoelectric material, and
a voltage application circuit applying a voltage to the pressing pillar in accordance with the temperature.

15. The transistor of claim 1, wherein
the stress application section is a stress application film formed on a surface of the formation substrate, which is opposite to the first semiconductor layer, and having a lower coefficient of thermal expansion than the formation substrate.

16. The transistor of claim 1, wherein
the stress application section is a stress application film formed on the second semiconductor layer, and having a higher coefficient of thermal expansion than the formation substrate.

17. The transistor of claim 1, wherein
a maximum value of the stress applied to the transistor body by the stress application section is a value at which a curvature radius of the formation substrate is not less than 250 m.

18. A transistor control system comprising:
a transistor body including a formation substrate, a first semiconductor layer and a second semiconductor layer which are sequentially stacked on the formation substrate, the second semiconductor layer having a wider bandgap than the first semiconductor layer;
a temperature detection section detecting a temperature of the transistor body; and
a stress application section applying tensile stress at a level corresponding to an output of the temperature detection section to the second semiconductor layer.
